(19) United States
(12) Patent Application Publication
(10) Pub. No.: US 2010/0206717 A1
(43) Pub. Date: Aug. 19, 2010

(54) METHOD AND APPARATUS FOR MANUFACTURING MAGNETIC RECORDING MEDIUM

(75) Inventor: Gohei Kurokawa, Ichihara-shi (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Tokyo (JP)

(21) Appl. No.: 12/668,366

(22) PCT Filed: Jul. 9, 2008
(86) PCT No.: PCT/JP2008/062388

§ 371 Date: May 4, 2010

(30) Foreign Application Priority Data
Jul. 11, 2007 (JP) 2007-182529

(51) Int. Cl. C23C 14/35; C23C 14/22

(52) U.S. Cl. 204/192.15; 204/298.15

(57) ABSTRACT

The present invention provides a method for manufacturing a magnetic recording medium by mounting a substrate for film formation on a carrier, sequentially transporting said substrate into a plurality of connected chambers, and forming at least a magnetic film and a carbon protective film on said substrate for film formation within said chambers, wherein said method comprises a step of forming a metal film on a carrier surface, which is performed following a step of removing a magnetic recording medium from said carrier following film formation, but prior to a step of mounting a substrate for film formation on said carrier.

### TECHNICAL FIELD

The present invention relates to a method and apparatus for manufacturing a magnetic recording medium used in a hard disk device or the like, and more specifically, relates to a method and apparatus for manufacturing a magnetic recording medium in which the generation of dust and gas from a carbon film that has accumulated on the surface of a substrate-supporting carrier is reduced.

Priority is claimed on Japanese Patent Application No. 2007-182529, filed Jul. 11, 2007, the content of which is incorporated herein by reference.

### BACKGROUND ART

In recent years, the improvements in the recording density of magnetic recording media has been dramatic, particularly in the field of magnetic disks, and recent recording densities have particularly increased at an extraordinary rate equivalent to an increase of approximately 100-fold in the last 10 years. Many different technologies are responsible for these huge improvements in recording density, but one of the key technologies has been technology for controlling the sliding characteristics between the magnetic head and the magnetic recording medium.

Since the CSS (contact start-stop) method known as the Winchester system, in which the basic operations involve contact sliding—head lifting—contact sliding between the magnetic head and the magnetic recording medium, has become the main system employed within hard disk drives, sliding of the head on the recording medium has become an unavoidable necessity, and therefore problems relating to tribology between the magnetic head and the magnetic recording medium are currently an unavoidable technical issue. As a result, the abrasion resistance and sliding resistance of the surface of a magnetic recording medium play an important role in determining the reliability of the medium, and intensive efforts continue to be directed towards the development and improvement of protective films and lubricating films and the like for lamination onto the magnetic film.

Various materials have been proposed as protective films for magnetic recording media, but from the overall viewpoints of film formability and durability and the like, carbon films are mainly employed. Carbon films are generally formed by sputtering methods, and the conditions during film formation are vividly reflected in either the corrosion resistance of the carbon film or the CSS characteristics, and are therefore extremely important.

Further, in order to improve the recording density, it is desirable to reduce the flying height of the magnetic head and increase the rotational speed of the medium, and therefore the magnetic recording medium requires a higher level of sliding durability.

On the other hand, in order to reduce spacing loss and thereby increase the recording density, the thickness of the protective film needs to be reduced as far as possible, for example to a film thickness of not more than 100 Å. There are strong demands for a protective film which is not only smooth, but also thin and tough.

However, when a carbon protective film formed by a conventional sputtering film formation method is reduced in thickness as far as possible, for example down to a film thickness of 100 Å or less, the durability of the formed film may be unsatisfactory.

Accordingly, methods that employ sputter method and plasma CVD method are becoming widespread as methods capable of forming carbon protective films having higher strengths than those obtainable using sputtering methods.

However, in those methods where the carbon protective film is formed using sputter method and plasma CVD method, inside the film formation apparatus, carbon is not only formed on the surface of the substrate, but also accumulates on the surfaces of the carrier that supports the substrate. When the amount of this type of carbon accumulated on exposed surfaces increases, factors such as internal stress cause the film formed from the accumulated carbon to peel away from the exposed surface. If the particles of carbon generated as a result of this type of peeling adhere to the substrate surface, then protrusions tend to be formed on the carbon protective film, resulting in localized film thickness abnormalities that can cause product defects. Particularly in those cases where the carbon protective film is formed using a plasma CVD method, the resulting film composed of carbon has a higher degree of hardness and higher internal stress than a carbon protective film formed using a conventional sputtering method, and therefore the amount of generated carbon particles is large, and the type of film thickness abnormalities mentioned above tend to be particularly problematic.

Methods of removing a carbon film accumulated on the surface of a substrate-supporting carrier by ashing the carbon film using an oxygen plasma have been proposed to prevent the generation of the types of particles described above (for example, see Japanese Unexamined Patent Application, First Publication No. Hei 11-229150, and Japanese Unexamined Patent Application, First Publication No. 2002-025047). Further, a treatment for suppressing peeling of accumulated material from an electrode by roughening the surface of the carrier has been used to prevent the peeling of an accumulated film from the surface of a substrate-supporting carrier (for example, see Japanese Unexamined Patent Application, First Publication No. 2006-173343).

Recently, there have been considerable demands for further improvements in the cleanliness of the surface of magnetic recording media in order to enable further improvements in the recording density of the magnetic recording media. However, the methods described above alone are not able to satisfactorily reduce the generation of particles, because although thorough ashing occurs in those regions such as the edges of the carrier where the plasma is readily concentrated, satisfactory ashing tends to be unobtainable in regions where the plasma is less readily concentrated, such as the flat surfaces of the carrier. Accordingly, reducing magnetic recording media defects caused by carbon protective film particles is currently a significant problem.

As described above, one of the causes of particle generation from the carbon protective film is the fact that improving the cleanliness of the carrier that supports the substrate is very difficult, and methods of improving this level of cleanliness have been keenly sought.

Further, according to research conducted by the inventors of the present invention, the carbon film accumulated on the carrier surfaces is not completely removed by the ashing treatment described above, and residues tend to remain on the carrier, mainly on the flat surfaces of the carrier. These residues are transported into other film formation chambers together with the carrier, and have also been confirmed as a component of the outgas emitted inside the vacuum chamber. In order to further increase the recording density of a magnetic recording medium while achieving a stable level of product stability, the emission within the vacuum chamber of components other than the intentionally used process gases must be avoided, and improvements in this area are also required.

### DISCLOSURE OF INVENTION

### Problems to be Solved by the Invention

The present invention takes the above circumstances into consideration, with an object of providing a manufacturing method in which, during formation of a carbon protective film on a substrate using a CVD method, by suppressing the generation of particles from the carbon film accumulated on the carrier that supports the substrate, and suppressing the emission of outgas for which the production source is the accumulated carbon film on the carrier surface, a magnetic recording medium can be manufactured that has a high recording density, excellent recording and reproduction characteristics, and stable quality.

### Means to Solve the Problems

As a result of intensive and concerted research aimed at achieving the above object, the inventors of the present invention discovered that when a residual carbon film accumulates on a substrate-supporting carrier during formation of a carbon protective film on a substrate, the generation of dust from the carbon protective film and the emission of outgas from the carrier could be effectively suppressed by using a magnetron sputtering method to form a metal film on the carrier surface, thereby coating the residual accumulated carbon film, with this metal film formation step conducted following the step of removing the magnetic recording medium from the carrier following film formation, but prior to the step of mounting a substrate for film formation on the carrier, and they were therefore able to complete the present invention. In other words, the present invention relates to the aspects described below.

(1) A method for manufacturing a magnetic recording medium by mounting a substrate for film formation on a carrier, sequentially transporting said substrate into a plurality of connected chambers, and forming at least a magnetic film and a carbon protective film on said substrate for film formation within said chambers, wherein said method comprises a step of forming a metal film on a carrier surface, which is performed following a step of removing a magnetic recording medium from said carrier following film formation, but prior to a step of mounting a substrate for film formation on said carrier.
(2) The method for manufacturing a magnetic recording medium according to (1) above, wherein said step of forming a metal film on a carrier surface is conducted by a magnetron discharge sputtering method that uses rotating magnetic field assistance.
(3) The method for manufacturing a magnetic recording medium according to (1) or (2) above, wherein said metal film formed on said carrier surface is a metal material having low oxidative reactivity.
(4) The method for manufacturing a magnetic recording medium according to (3) above, wherein said metal material having low oxidative reactivity comprises one element selected from the group consisting of Ru, Au, Pd, Pt, Cr and Ti.
(5) An apparatus for manufacturing a magnetic recording medium, having a plurality of connected chambers, and in which a plurality of thin films are laminated on a substrate for film formation by sequentially transporting said substrate to each of said chambers using a carrier and then forming a thin film on said substrate for film formation, wherein said apparatus comprises a chamber for removing a magnetic recording medium from a carrier following film formation, and a chamber for mounting a substrate for film formation on a carrier from which a substrate has been removed, and also comprises, between said chambers, a chamber for forming a metal film on a carrier surface.

### EFFECT OF THE INVENTION

By using the method for manufacturing a magnetic recording medium of the present invention, which employs a cleanliness retention technique that uses a metal film coating formed on a substrate-supporting carrier, when a carbon protective film is formed on both surfaces of a magnetic recording medium substrate, the problem that arises when the carbon film that accumulates on the carrier surface detaches to form particles that subsequently adhere to the substrate can be effectively suppressed

Furthermore, by coating the carrier surface with a metal film, outgas from the carrier can be suppressed.

### BRIEF DESCRIPTION OF THE DRAWINGS

FIG. 1 is a schematic longitudinal sectional view illustrating one example of a magnetic recording medium manufactured using the method for manufacturing a magnetic recording medium according to the present invention.

FIG. 2 is a schematic illustration of an apparatus for manufacturing a magnetic recording medium according to the present invention.

FIG. 3 is a schematic illustration of a sputtering chamber within an apparatus for manufacturing a magnetic recording medium according to the present invention.

FIG. 4 is a side view illustrating a carrier within an apparatus for manufacturing a magnetic recording medium according to the present invention.

FIG. 5 is a schematic illustration of a metal film coating device according to the present invention.

### DESCRIPTION OF THE REFERENCE SYMBOLS

1: Substrate cassette-transferring robot mount
2: Substrate supply robot chamber
3: Substrate cassette-transferring robot
3A, B: Carrier metal film formation chamber
4, 7, 14, 17: Corner chamber for rotating carrier
5, 6, 8 to 13, 15, 16: Sputtering chamber or substrate heating chamber
18 to 20: Protective film formation chamber
22: Substrate removal robot chamber
23, 24: Substrate for film formation (non-magnetic substrate)
25: Carrier
26: Support base
27: Substrate mount
28: Plate
29: Circular through-hole
30: Support member
34: Substrate supply robot
49: Substrate removal robot
52: Substrate installation chamber
54: Substrate removal chamber
80: Non-magnetic substrate
81: Seed layer
82: Undercoat film
83: Magnetic recording film
84: Protective film
85: Lubricant layer
501: Metal film coating device
502: Chamber
503: Substrate-supporting carrier
504: Magnet
505: Target material
506: Exhaust volume control valve
507: Direct current power source
508: High-frequency power source
509: Gas inlet tube
510: Drive device
511: Magnetic field

### BEST MODE FOR CARRYING OUT THE INVENTION

Embodiments of the carrier cleanliness improvement produced by forming a metal film coating on the carrier in accordance with the present invention are described below.

First is a description of a magnetic recording medium that represents one example of the thin film laminate produced using the method for manufacturing a magnetic recording medium according to the present invention.

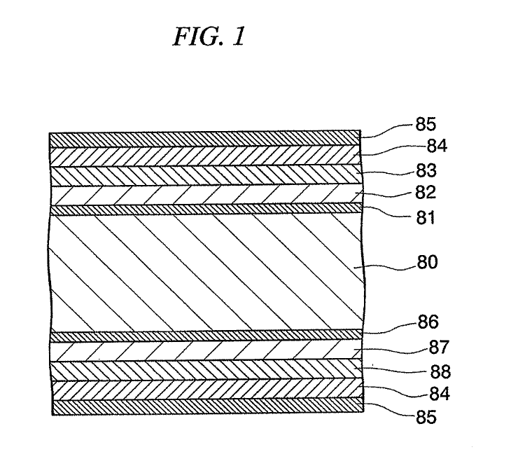

FIG. 1 is a schematic longitudinal sectional view illustrating one example of a magnetic recording medium (thin film laminate) manufactured using the method for manufacturing a magnetic recording medium according to the present invention.

As illustrated in FIG. 1, this magnetic recording medium includes a non-magnetic substrate 80, and a seed layer 81, an undercoat film 82, a magnetic recording film 83, a protective film 84 and a lubricant layer 85 laminated sequentially on both surfaces or one surface of the non-magnetic substrate 80.

Examples of materials that may be used for the non-magnetic substrate 80 include the types of Al alloy substrates having a NiP plating film formed thereon (hereafter referred to as NiP-plated Al substrates) typically used as substrates for magnetic recording media, as well as glass substrates, ceramic substrates, flexible resin substrates, and substrates prepared by coating one of these non-magnetic substrates with NiP using either a plating method or a sputtering method.

Further, the surface of the non-magnetic substrate 80 may be subjected to a texturing treatment for the purposes of achieving more favorable electromagnetic conversion characteristics, imparting the substrate with in-plane magnetic anisotropy to improve the heat fluctuation characteristics, and/or removing any polishing marks.

The seed layer (lower undercoat layer) 81 formed on the non-magnetic substrate 80 controls the crystal orientation of the film formed directly thereon. Examples of the material used in forming the seed layer 81 include Ti, TiCr, Hf, Pt, Pd, NiFe, NiFeMo, NiFeCr, NiAl, NiTa and NiNb, which may be selected and used in accordance with the film formed directly on the seed layer.

Furthermore, the seed layer 81 need not necessarily be formed from only a single layer, and if required, may be formed as a multilayer structure by laminating a plurality of films having either the same composition or different compositions.

Conventional non-magnetic undercoat films may be used as the undercoat film 82, including single element films of Cr, Ti, Si, Ta or W or the like, or alloy films that also include other elements, provided the crystallinity is not impaired. In terms of the relationship with the magnetic recording film 83 described below, the undercoat film 82 is preferably either composed solely of Cr, or formed from an alloy of Cr containing one or more other elements selected from among Mo, W, V and Ti. In some cases, depending on the type of the non-magnetic substrate 80, laminating a film of NiAl as the undercoat film 82 may yield a dramatic improvement in the SNR, and may therefore be desirable.

There are no particular limitations on the thickness of the undercoat film 82, provided the desired coercive force can be obtained, although the thickness is preferably within a range from 5 to 40 nm, and is more preferably from 10 to 30 nm. If the thickness of the undercoat film 82 becomes overly thin, then the crystal orientation of either the magnetic recording film 83 formed on the undercoat film 82, or if employed, the non-magnetic intermediate film formed between the undercoat film 82 and the magnetic recording film 83, tends to deteriorate, causing an undesirable decrease in the SNR. In contrast, if the thickness of the undercoat film 82 is too large, then the particle size of the particles within the undercoat film 82 tends to increase, resulting in an accompanying increase in the particle size within the magnetic recording film 83 or the non-magnetic intermediate film formed on the undercoat film 82, which causes an undesirable decrease in the SNR.

Furthermore, the undercoat film 82 need not necessarily be formed from only a single layer, and if required, may be formed as a multilayer structure by laminating a plurality of films having either the same composition or different compositions.

There are no particular limitations on the magnetic recording film 83, provided it is a magnetic film capable of yielding the desired coercive force, although by using a Co alloy layer represented by a formula CoₐCr_{b}Pt_{c}Ta_{d}ZrₑCu_{f}Ni_{g} (wherein a, b, c, d, e, f and g indicate the composition ratio, and respectively represent b: 16 to 25 at %, c: 0 to 10 at %, d: 1 to 7 at %, e: 0 to 4 at %, f: 0 to 3 at %, g: 0 to 10 at %, and a: the remainder) the magnetic anisotropy can be increased, enabling the coercive force to be further improved.

In the magnetic recording medium of this embodiment, the protective film 84 is formed on the magnetic recording film 83 to prevent scratching of the magnetic recording film 83 caused by contact between the head and the surface of the medium. Conventional materials may be used for the protective film 84, and examples include single component films formed from C, SiO₂ or ZrO₂ or the like, or films containing these materials as the main component and also containing other added elements.

The protective film 84 may be formed using a method such as sputtering method, an ion beam method or plasma CVD method or the like.

The thickness of the protective film 84 is typically within a range from 2 to 20 nm. Setting the thickness of the protective film 84 within a range from 2 to 9 nm is preferred in terms of reducing spacing loss.

The lubricant layer 85 is formed on the surface of the protective film 84. Examples of materials that may be used as the lubricant include fluorine-based liquid lubricants such as perfluoroethers (PFPE), and solid lubricants such as fatty acids. Conventional methods may be used for applying the lubricant, including dipping methods and spin coating methods.

Next is a description of a method for manufacturing the magnetic recording medium that represents one example of a thin film laminate of the present invention.

First is a description of the apparatus for manufacturing a magnetic recording medium that is used in the method for manufacturing a magnetic recording medium according to the present invention.

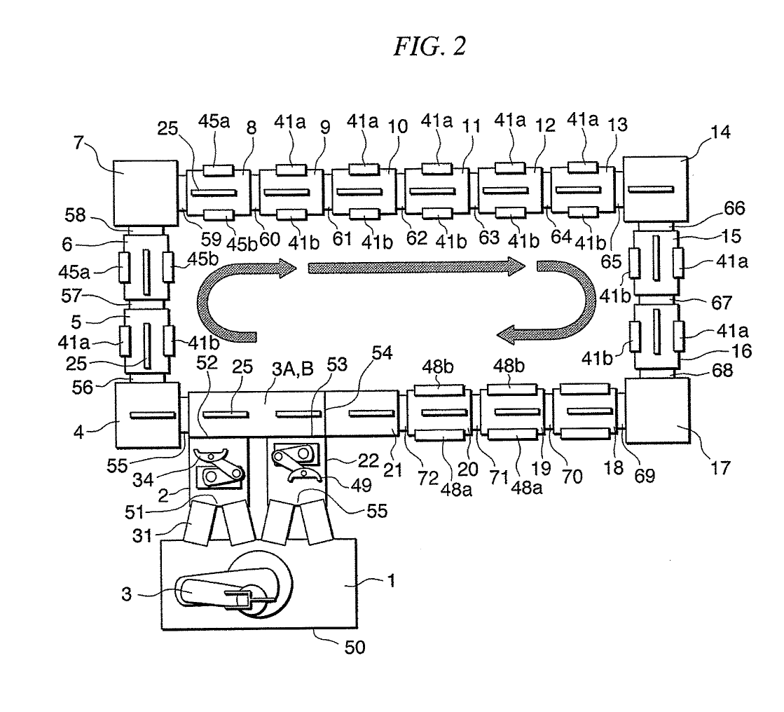

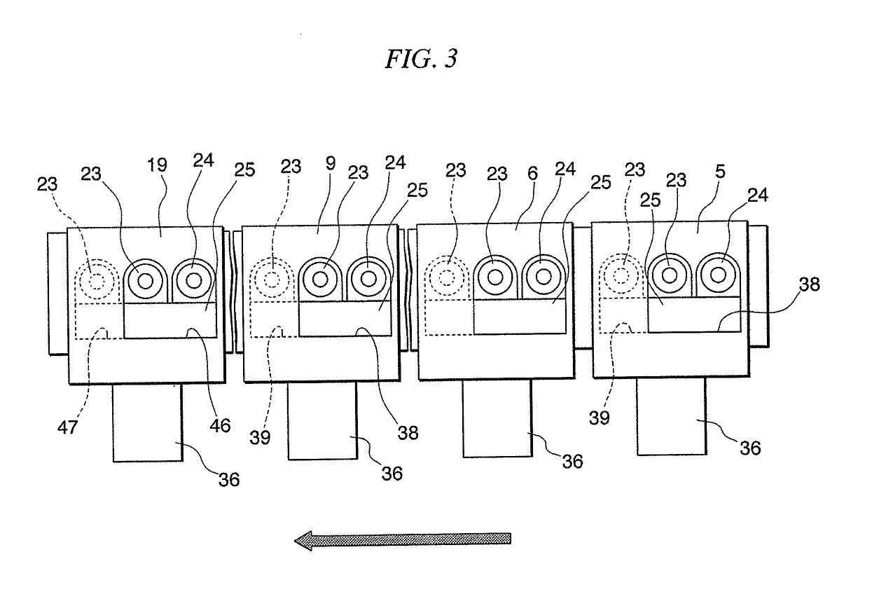

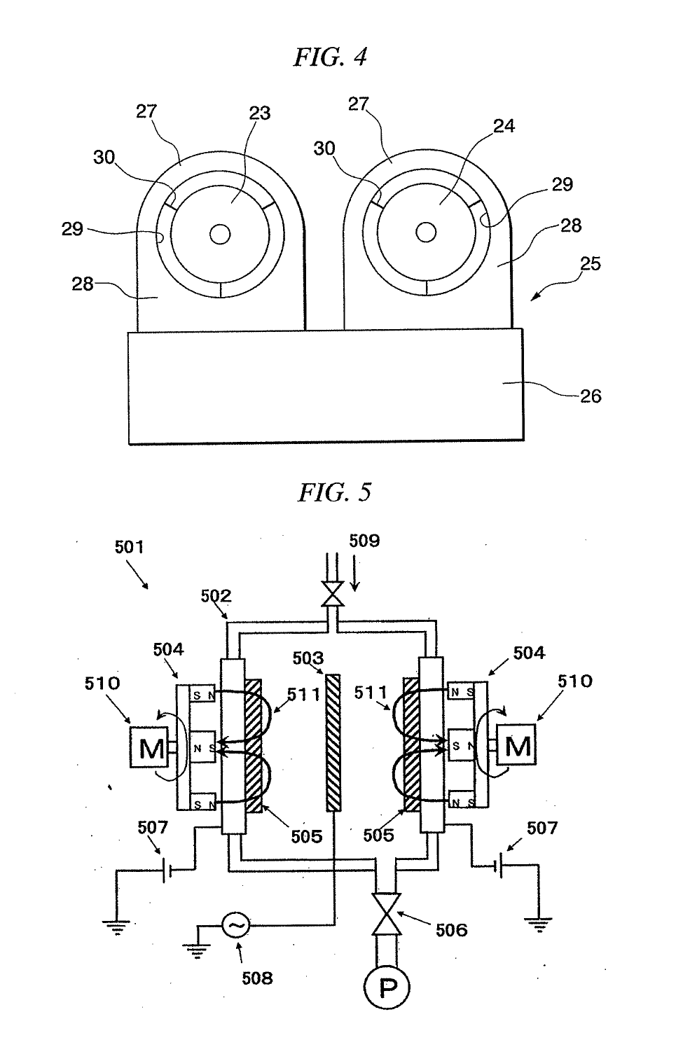

FIG. 2 is a schematic diagram illustrating one example of the apparatus for manufacturing a magnetic recording medium according to the present invention, FIG. 3 is a schematic illustration of a sputtering chamber within the apparatus for manufacturing a magnetic recording medium according to the present invention, and FIG. 4 is a side view illustrating a carrier within the apparatus for manufacturing a magnetic recording medium according to the present invention. In FIG. 3, the carrier indicated by the solid lines represents the state when the carrier is stopped at a first film formation position, whereas the carrier indicated by the dashed lines represents the state when the carrier is stopped at a second film formation position. In other words, in the sputtering chambers illustrated for this example, two targets are positioned opposing the substrate within the chamber, and therefore film formation is first conducted onto the substrate on the left side of the carrier with the carrier stopped at the first film formation position, the carrier is subsequently moved to the position indicated by the dashed lines, and film formation is then conducted onto the substrate on the right side of the carrier with the carrier stopped at the second film formation position. In those cases where four targets are positioned opposing the substrates within the chamber, this type of movement of the carrier becomes unnecessary, and film formation onto the substrates supported on the left and right sides of the carrier can be conducted simultaneously.

As illustrated in FIG. 2, this magnetic recording medium manufacturing apparatus includes a substrate cassette-transferring robot mount 1, a substrate cassette-transferring robot 3, a substrate supply robot chamber 2, a substrate supply robot 34, a substrate installation chamber 52, corner chambers 4, 7, 14 and 17 for rotating the carrier, sputtering chambers and substrate heating chambers 5, 6, 8 to 13, 15 and 16, protective film formation chambers 18 to 20, a substrate removal chamber 54, a substrate removal robot chamber 22, a substrate removal robot 49, a carrier metal film formation chamber 3A, B, and a plurality of carriers 25 with a plurality of substrates for film formation (non-magnetic substrates) 23 and 24 mounted thereon.

A vacuum pump is connected to each of these chambers 2, 52, 4 to 20, 54, 3A and B, and each of the carriers 25 is transported sequentially into each of the chambers, the insides of which are maintained in a reduced pressure state by operation of the vacuum pumps. By forming thin films (such as the seed layer 81, the undercoat film 82, the magnetic recording film 83 and the protective film 84) on both surfaces of the mounted film formation substrates 23 and 24 inside each of the film formation chambers, a magnetic recording medium that represents one example of a thin film laminate can be obtained.

For example, the magnetic recording medium manufacturing apparatus of this embodiment can be configured as an inline type film formation apparatus. In the magnetic recording medium manufacturing apparatus of this embodiment, the seed layer 81, the undercoat film 82, the magnetic recording film 83 and the protective film 84 may be formed with a two-layer configuration, a two-layer configuration, a four-layer configuration, and a two-layer configuration respectively.

As illustrated in FIG. 4, the carrier 25 includes a support base 26 and a plurality of substrate mounts 27 (two in the case of this embodiment) provided on the upper surface of the support base 26.

Each of the substrate mounts 27 is composed of a plate 28 of substantially the same thickness as the substrates for film formation (the non-magnetic substrates) 23 and 24, in which is formed a circular through hole 29 having a slightly larger diameter than the outer periphery of the film formation substrates 23 and 24, with a plurality of support members 30 extending from the periphery of the through hole 29 towards the interior of the through hole 29. The film formation substrates 23 and 24 are fitted inside the through holes 29 of the substrate mounts 27, and the edges of the substrates engage with the support members 30, thereby supporting and holding the film formation substrates 23 and 24. These substrate mounts 27 are provided in alignment on the upper surface of the support base 26 so that the main surfaces of the two mounted film formation substrates 23 and 24 are not only substantially orthogonal relative to the upper surface of the support base 26, but are also positioned within substantially the same plane. In the following description, the two film formation substrates 23 and 24 mounted on the substrate mounts 27 are referred to as the first film formation substrate 23 and the second film formation substrate 24 respectively.

The substrate cassette-transferring robot 3 supplies the film formation substrates 23 and 24 from a cassette in which the substrates are housed to the substrate installation chamber 2, and also extracts magnetic disks (namely, the film formation substrates 23 and 24 with each of the films 81 to 84 formed thereon) that have been removed from the substrate removal chamber 22. These substrate installation and removal chambers 2, 22 each have an external opening on one side of the chamber, and doors 51 and 55 that open and close the opening.

Further, neighboring walls between each of the chambers 2, 52, 4 to 20, 54, 3A and B are mutually interconnected, and a gate valve is provided within the connection between each pair of chambers, so that when these gate valves are closed, the inside of each chamber is an independently sealed space.

The corner chambers 4, 7, 14 and 17 are chambers used for altering the moving direction of the carrier 25, and each of these chambers is provided with a mechanism, not shown in the drawing, for rotating the carrier and transferring it to the next chamber.

The protective film formation chambers 18 to 20 are chambers for forming a protective film, using a CVD method or the like, on the surface of the outermost layer formed on the first film formation substrate 23 and the second film formation substrate 24. A reactive gas supply tube and a vacuum pump, which are not illustrated in the drawing, are connected to each of the protective film formation chambers.

The reactive gas supply tube is provided with a valve, the opening and closing of which is controlled by a control mechanism not shown in the drawing, and a gate valve for the vacuum pump, the opening and closing of which is controlled by a control device not shown in the drawing, is provided between the vacuum pump and the protective film formation chamber. By controlling the opening and closing of this valve and pump gate valve, the supply of gas from the sputtering gas supply tube, the pressure inside the protective film formation chamber, and the exhausting of gas from the chamber can be controlled.

When film formation is conducted within the protective film formation chamber using a CVD method, a reactive gas is supplied to the chamber, a high-frequency voltage is applied between an electrode and the film formation substrate to generate a discharge between the two, and this discharge causes the reactive gas introduced into the chamber to adopt a plasma state. The active radical and ion reactants generated within the plasma are formed on the surface of the outermost layer formed on the film formation substrate 23, thus forming a protective film.

In the substrate removal chamber 54, the first film formation substrate 23 and the second film formation substrate 24 mounted on the carrier 25 are removed using the robot 49. Subsequently, the carrier 25 is transported into the carrier metal film formation chamber 3A, B.

In the present invention, a step of forming a metal film on the carrier surface is provided prior to the step of mounting a substrate for film formation on the carrier. By providing this type of step, the emission of outgas from the carrier can be reduced.

In the present invention, the metal material used for coating the carrier in order to block the release of outgas may be either a magnetic material or a non-magnetic material, although if a film of a magnetic material is formed, then the carrier itself becomes magnetic, and therefore a non-magnetic material is preferably used. Furthermore, the material itself may be composed of either a single metal element or a metal alloy containing a plurality of elements, although an alloy composition that includes metal oxides is undesirable as it may result in the release of gas from the oxides. Moreover, the use of a metal material that exhibits a high level of oxidative reactivity is also undesirable.

In the present invention, when forming the film of the metal material on the carrier surface, if the film is too thin, then the suppression effect on the outgas is minimal, whereas if the film is too thick, the total amount of the metal film accumulated on the carrier increases significantly, which may cause peeling of the film from the carrier, and also increases the frequency with which the carrier must be replaced. For these reasons, the film thickness is preferably within a range from 30 to 200 Å (3 to 15 nm), and is more preferably within a range from 50 to 100 Å (5 to 10 nm). Moreover, the film is preferably formed over the entire carrier surface, without installing the types of shields that are widely used for restricting the film formation region.

An apparatus 501 illustrated in FIG. 5 represents one example of the apparatus used for conducting the formation of a metal film coating on the carrier in accordance with the present invention. This apparatus 501 is used for coating the surface of the carrier with a metal film, and a chamber 502 includes a carrier 503 for supporting a substrate within a state of vacuum. At this point, no substrate is mounted on the carrier 503. Magnets 504 for forming a rotating magnetic field are installed outside the chamber, and are each rotated at an arbitrary rate of rotation using a drive device 510. A metal target material 505 that acts as the material used in forming the metal film coating on the carrier is installed inside the chamber, and a magnetic field 511 from the magnet 504 penetrates into the chamber 502 and is formed on the surface of the target material 505. The chamber 502 is provided with an exhaust port, and an exhaust pump is used to extract and remove gases from inside the chamber 502. An exhaust volume control valve 506 that is controlled by a control device not shown in the drawing can be used to set the exhaust volume at a desired level. High-frequency electrical power is applied to the carrier 503 inside the chamber 502 using a high-frequency power source 508. A direct current is applied to the target material 505 from a direct current power source 507. A gas inlet tube 509 is provided in the chamber 502 to enable the treatment gas to be introduced into the chamber 502.

The power source 507 supplies the electrical power that causes discharge of the metal target material 505 within the gas composed mainly of Ar, during the coating of the carrier surface in accordance with the present embodiment. The power source 7 is preferably a DC power source or a pulsed DC power source. Further, the capacity of the power source 507 is preferably sufficient to supply an electrical power of 50 to 1,500 W.

The gas 509 introduced into the chamber during the carrier coating treatment is preferably a gas containing argon as the main component. A mixed gas containing oxygen or nitrogen mixed with argon may also be used, but using this type of mixed gas tends to invite a lowering in the degree of vacuum caused by gas adsorption on the carrier, and is therefore undesirable. Further, when generating the discharge from the metal target used for forming the coating film, it is necessary to ensure that the film formation rate per unit of time is maintained at the maximum possible level, and therefore the use of an argon gas having a purity of not less than 99.9% is fundamentally preferred.

As illustrated in FIG. 5, the formation of a metal film coating on the carrier in accordance with the present embodiment involves housing the carrier 503, with no substrate mounted thereon, inside the chamber 502 that is held in a vacuum state of at least 1×10⁻⁴ Pa, introducing a gas containing mainly argon from the gas inlet tube 509, using the exhaust volume control valve 506 to regulate the exhaust volume and hold the pressure inside the chamber within a range from 0.5 to 1.0 Pa, and then applying a direct current electrical power to the metal target material 505 from the power source 507. Either a direct current pulsed power or high-frequency power may be used, but in terms of achieving a favorable film formation rate per unit of time, the use of a direct current power is preferred, and a discharge is generated within a power range from 100 to 1,500 W. In terms of ensuring applicability with practical industrial production, the treatment is preferably completed within a treatment time of approximately 1 to 5 seconds.

The electrical power applied to the target material causes ionization of the argon gas introduced into the chamber, thereby converting the gas to an argon plasma. In order to focus the generated argon plasma, the plasma is imparted with kinetic energy by the rotating magnets 504 positioned outside the chamber, causing the plasma to flow across the target material in a diagonal direction while sweeping out a helical trajectory. Upon impact with the surface of the target material, the argon gas plasma causes metal atoms of the target material to fly off, thereby causing sputtering. The argon plasma that does not contribute to the sputtering returns to the helical trajectory, and contributes to the sputtering process when it next impacts the target material. Accordingly, using a rotating magnetic field causes a dramatic increase in the number of chances for impact between the argon plasma and the target material, resulting in an improvement in the coating rate of the carrier surface per unit of time. The rotating magnets are installed in opposing positions with the target material and the carrier sandwiched therebetween, but if the same poles of the opposing magnetic fields are synchronized with the same phase, then repulsion between the magnetic fields causes the plasma flow to lose uniformity, and therefore the matching poles are preferably in an asynchronous antiphase state. Furthermore, the rotational speed of the rotating magnets used for forming the rotating magnetic fields is typically within a range from 60 to 800 rpm, and is preferably from 300 to 600 rpm.

The metal material used for coating the carrier in order to block the release of outgas may be either a magnetic material or a non-magnetic material, although if a film of a magnetic material is formed, then the holder itself becomes magnetic, and therefore a non-magnetic material is preferably used. Furthermore, the material itself may be composed of either a single metal element or a metal alloy containing a plurality of elements, although an alloy composition that includes metal oxides is undesirable as it may result in the release of gas from the oxides. Moreover, the use of a metal material that exhibits a high level of oxidative reactivity is also undesirable. In the present invention, the metal used for coating the carrier is preferably Ru, Au, Pd, Pt, Cr or Ti.

Furthermore, when forming the film on the carrier surface, if the film is too thin, then the suppression effect on the outgas is minimal, whereas if the film is too thick, the total amount of the metal film formed on the holder increases significantly, which may cause peeling of the film from the holder, and also increases the frequency with which the holder must be replaced. For these reasons, the film thickness is preferably within a range from 30 to 200 Å (3 to 15 nm), and is more preferably within a range from 50 to 100 Å (5 to 10 nm). Moreover, the film is preferably formed over the entire holder surface, without installing the types of shields that are widely used for restricting the film formation region.

### EXAMPLES

Examples of the formation of a metal film coating on the carrier according to the present invention are described below, although the present invention is not limited solely to these examples.

### Example 1

A non-magnetic substrate composed of a NiP-plated aluminum substrate was supplied to the chamber of a sputtering film formation apparatus using a substrate transport device, and the inside of the chamber was evacuated. Following completion of the evacuation process, the substrate transport device was used to mount the substrate on an A5052 aluminum alloy carrier within the vacuum environment inside the chamber. The surface of the carrier had been subjected to a sandblasting treatment with #20 to 30 SiC particles. An undercoat film composed of Cr and a magnetic recording layer composed of Co, which represent layers required to form the magnetic recording medium, were formed on the carrier-mounted substrate inside the sputtering chamber, and a carbon protective film of thickness 50 Å was then formed on the substrate by plasma CVD in a CVD chamber. At this time, carbon was also deposited on the carrier surfaces near the substrate.

Subsequently, the substrate was removed from the carrier inside the chamber using the substrate transport device. The carrier from which the substrate had been removed was then transported into the next chamber. Subsequent treatments are described below using FIG. 5 for reference. Following transfer of the carrier into the next chamber, 100% argon gas was supplied to the chamber, the pressure inside the chamber was held at 0.8 Pa, and a 1,000 W direct current was applied for 1 second from the power source 507 to the CrTi alloy target material 505, thereby causing magnetron sputtering of the CrTi alloy target material 505 in the presence of the rotating magnets 504, and forming a sputtered film of the material of the CrTi alloy target 505 with a thickness of approximately 50 Å on the surface of the carrier. In this investigation, four targets were installed within the single chamber, enabling the film formation to be performed simultaneously on two substrates mounted on the carrier. Further, in order to enable coating of the carrier over a wider area, the distance from the target material to the carrier surface was set to 75 mm, and the treatment was conducted without installing a shield for restricting the discharge region.

In order to confirm the effect of this metal film coating in suppressing the release of outgas from the carrier, a gas detector was installed in the chamber 506, and the gas components released into the chamber by the carrier were evaluated. The results of the evaluations are shown in Table 1.

### Example 2

### Comparative Examples 1 and 2

A carrier metal film coating treatment was performed in the same manner as example 1. The treatment conditions and evaluation results are detailed in Table 1.

As is evident from Table 1, it was confirmed that formation of a metal film on the carrier surface caused a reduction in the ion current of the above gas components.

TABLE 1

| | CVD | Metal film coating | | | |
|---|---|---|---|---|---|
| | carbon film | | Thickness | Ion current (A) | |
| | (Å) | Material | (Å) | CO | CO₂ |
| Comparative | 0 | CrTi | 1,000 | 1.4E−12 | 1.4E−12 |
| example 1 | | | | | |
| Comparative | 50 Å | None | | 8.0E−12 | 7.4E−12 |
| example 2 | | | | | |
| Example 1 | 50 Å | CrTi | 50 | 2.5E−12 | 2.0E−12 |
| Example 2 | 50 Å | Ru | 50 | 1.9E−12 | 1.8E−12 |

### INDUSTRIAL APPLICABILITY

According to the method for manufacturing a magnetic recording medium of the present invention, which employs a cleanliness retention technique that involves forming a metal film coating on the substrate-supporting carrier, when a carbon protective film is formed on both surfaces of the magnetic recording medium substrate, the problem wherein the carbon film that accumulates on the carrier surface detaches to form particles that subsequently adhere to the substrate itself can be suppressed.

Furthermore, by coating the carrier surface with a metal film, outgas from the carrier can be suppressed.

1. A method for manufacturing a magnetic recording medium by mounting a substrate for film formation on a carrier, sequentially transporting said substrate into a plurality of connected chambers, and forming at least a magnetic film and a carbon protective film on said substrate for film formation within said chambers, wherein
said method comprises a step of forming a metal film on a carrier surface, which is performed following a step of removing a magnetic recording medium from said carrier following film formation, but prior to a step of mounting a substrate for film formation on said carrier.

2. The method for manufacturing a magnetic recording medium according to claim 1, wherein said step of forming a metal film on a carrier surface is conducted by a magnetron discharge sputtering method that uses rotating magnetic field assistance.

3. The method for manufacturing a magnetic recording medium according to claim 1, wherein said metal film formed on said carrier surface is a metal material having low oxidative reactivity.

4. The method for manufacturing a magnetic recording medium according to claim 3, wherein said metal material having low oxidative reactivity comprises one element selected from the group consisting of Ru, Au, Pd, Pt, Cr and Ti.

5. An apparatus for manufacturing a magnetic recording medium, having a plurality of connected chambers, and in which a plurality of thin films are laminated on a substrate for film formation by sequentially transporting said substrate to each of said chambers using a carrier and then forming a thin film on said substrate for film formation, wherein
said apparatus comprises a chamber for removing a magnetic recording medium from a carrier following film formation, and a chamber for mounting a substrate for film formation on a carrier from which a magnetic recording medium has been removed, and also comprises, between said chambers, a chamber for forming a metal film on a carrier surface.

6. The method for manufacturing a magnetic recording medium according to claim 2, wherein said metal film formed on said carrier surface is a metal material having low oxidative reactivity.
